(19) United States
(12) Patent Application Publication
(10) Pub. No.: US 2003/0203567 A1
(43) Pub. Date: Oct. 30, 2003

(54) Method of fabricating capacitor with two step annealing in semiconductor device

(76) Inventor: Dong-Soo Yoon, Ichon-shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 10/316,832

(22) Filed: Dec. 12, 2002

(30) Foreign Application Priority Data
Apr. 26, 2002 (KR) 2002-22999

(51) Int. Cl. H01L 21/8234; H01L 21/8244; H01L 21/8242; H01L 21/20

(52) U.S. Cl. 438/253; 438/396; 438/240

(57) ABSTRACT

A forming capacitor method performing two steps of thermal treatment processes for preventing to generate a residual product having low permittivity at an interface between a dielectric and a bottom-electrode is disclosed. The method includes the steps of forming a bottom-electrode of a substrate, forming a dielectric on the bottom-electrode, performing a first thermal treatment process for crystallizing he dielectric, performing a second thermal treatment process for supplying oxygen to the dielectric and forming an upper-electrode on the dielectric. The above-mentioned processes of the present invention can restrain to produce the oxide having low permittivity, therefore a reliability of capacitor and electrical characteristics would be increased and improved.

### FIELD OF THE INVENTION

The present invention relates to a method preventing to generate a residual product having low permittivity at an interface between a dielectric layer and a bottom-electrode for improving a characteristic of a capacitor by performing two steps of thermal treatment process.

### DESCRIPTION OF RELATED ARTS

Recently, a capacitor used in a semiconductor memory element is constructed by stacking a bottom-electrode, a dielectric layer and an upper-electrode. A conventional method for forming a capacitor will be explained as referring to FIG. 1.

FIG. 1 is a flowchart illustrating the conventional capacitor forming process. Referring to FIG. 1, at first, the bottom-electrode of the capacitor is formed on a semiconductor substrate. A poly-silicon or metal can be used as the bottom-electrode of the capacitor and also multi-layer stacked construction can be used as the bottom-electrode of the capacitor.

After forming the bottom-electrode, the dielectric layer of the capacitor is formed on the bottom-electrode. A silicon composition including SiO₂ or Si₃N₄ has been used as the dielectric layer of the capacitor however, by increasing a degree of integration of a memory cell, new dielectric material having high permittivity is used recently for storing sufficient capacitance in a small capacitor.

High dielectric substances and feroelectric substances have many times higher permittivity than the conventional dielectric substances such as ONO, wherein the high elelectric substances are Ta₂O₅, Al₂O₃, SrTiO₃ or TaON and the feroelectric substances include (Bi, La)₄Ti₃O₁₂ (BLT), SrBi₂Ta₂O₉ (SBT), SrxBiy(TaiNbj)₂O₉ (SBTN), BaxSr(1−x)TiO₃ (BST) and Pb(Zr,Ti)O₃ (PZT). The high elelectric substances and the feroelectric substances have been recently studied actively since sufficient capacitance can be stored in a limited space of the high elelectric substances and the feroelectric substances and tantalum dielectrics such as Ta₂O₃ or TaON have been already used in the capacitor forming process.

In a case that the tantalum dielectrics are used as the dielectric layer of the capacitor, a thermal treatment process is performed for crystallizing the tantalum dielectrics layer and supplying oxygen to the tantalum dielectrics layer after depositing at a temperature over about 800° C.

After the above-mentioned thermal treatment process, the capacitor forming process is completed by forming the upper-electrode on the dielectric. Titanium nitride or poly silicon can be used as the upper-electrode of the capacitor and also precious metals such as platinum, iridium or ruthenium can be used.

As mentioned above, the conventional forming process of the tantalum dielectric layer performs the thermal treatment process at a temperature of over 800° C. for crystallizing the dielectric layer and supplying the oxygen after forming the dielectric layer.

In a case that the tantalum dielectric layer is deposited in a low temperature, the dielectric layer may be amorphorous state, not polycrystalline state and the tantalum dielectric layer with the amorphorous state has fewer dielectric constant than the tantalum dielectric layer with the polycrystalline state. Therefore, the conventional forming process of the tantalum dielectric layer requires over 800° C. of the thermal treatment process for depositing the tantalum dielectric layer with the polycrystalline state.

Also, in a case of the dielectric layer Ta₂O₅ or TaON, if the oxygen constituent is deficient, high permittivity of dielectric layer is decreased so the thermal treatment process is a necessary process for supplying the oxygen to the dielectric layer after deposing the dielectric layer. Conventionally, for crystallizing the dielectric layer and supplying the oxygen, a thermal treatment process is performed just once.

The conventional thermal treatment process for the deposition process of the dielectric layer is performed at over 800° C. temperature and is also performed on over 800° C. temperature at an ambient of oxygen gas after forming the dielectric therefore, an oxide is produced in an interface between the bottom-electrode and the dielectric layer. The produced oxide is another dielectric layer between the bottom-electrode and the dielectric layer and the produced oxide layer aggravates characteristics of leakage current and charging capacity.

### SUMMARY OF THE INVENTION

It is, therefore, an object of the present invention to provide a method of capacitor forming process for improving characteristics of a capacitor by preventing to produce an oxide having low permittivity during a thermal treatment process of a dielectric. In accordance with an aspect of the present invention, there is provided a method for forming capacitor of a semiconductor device, comprising: forming a bottom-electrode on a substrate; forming a dielectric layer on the bottom-electrode; performing a first thermal treatment process for crystallizing the dielectric layer; performing a second thermal treatment process for supplying oxygen to the dielectric; and forming an upper-electrode on the dielectric.

### BRIEF DESCRIPTION OF THE DRAWINGS(S)

The above and other objects and features of the present invention will become apparent from the following description of the preferred embodiments given in conjunction with the accompanying drawings, in which:

FIG. 1 is a flowchart illustrating the conventional capacitor forming process;

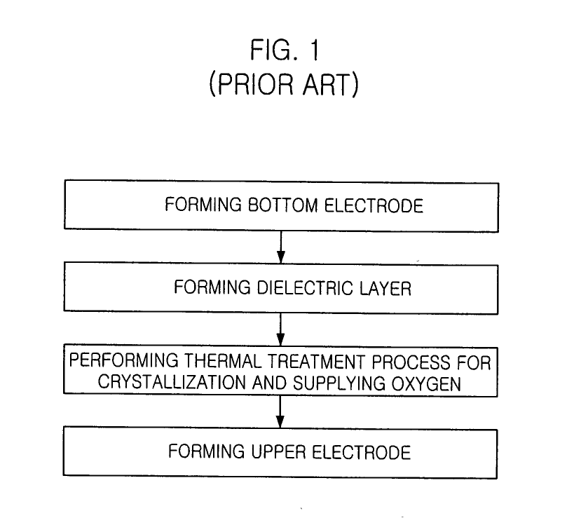

FIGS. 2A and 2B are sectional views of a capacitor forming process in accordance with the preferred embodiment of the present invention; and

FIG. 3 is a flowchart illustrating a capacitor forming process in accordance with the present invention.

### DETAILED DESCRIPTION OF THE INVENTION

Other objects and aspects of the invention will become apparent from the following description of the embodiments with reference to the accompanying drawings, which is set forth hereinafter.

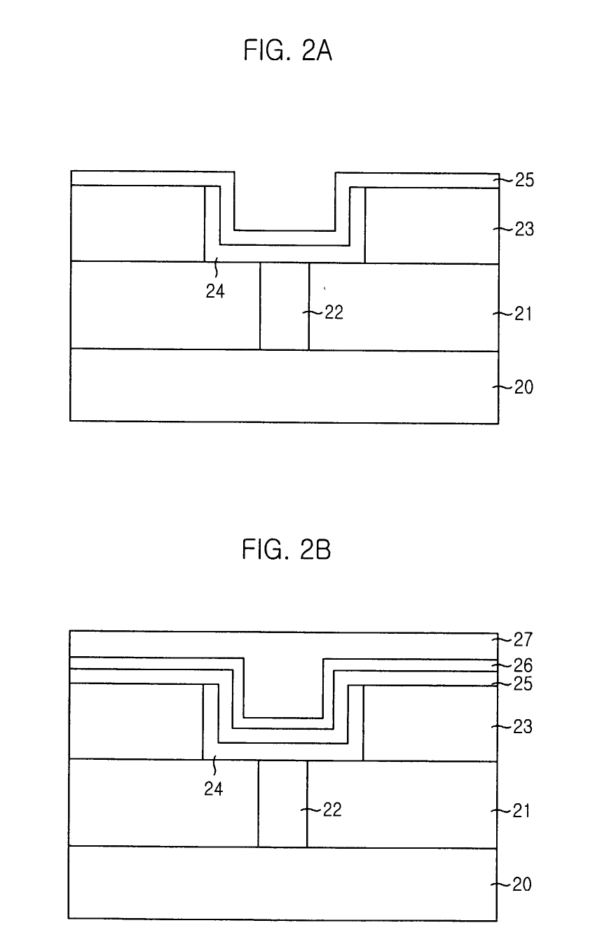

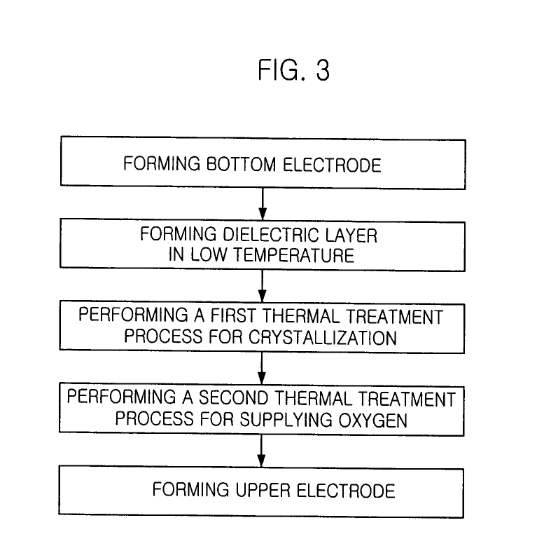

FIGS. 2A and 2B are a sectional view of a capacitor forming process in accordance with a preferred embodiment of the present invention and FIG. 3 is a flowchart illustrating a capacitor forming process in accordance with the present invention.

Referring to FIG. 2A, after a first insulating layer 21 is formed on a semiconductor substrate 20, a plug 22 is formed in middle of the first insulating layer 21 and connects a bottom-electrode 24 and the semiconductor substrate 20 by penetrating the first insulating layer 21. Poly-silicon and tungsten are used for a material of the plug 22 and a silicide layer for an ohmic contact and a diffusion barrier layer for preventing diffusion between substances are used as a typical construction of the plug 22.

After forming the plug 22, a second insulating layer 23 is formed on the first insulating layer 21. The insulating layer 23 also includes a trench hole. The trench hole is formed by selectively etching the second insulating layer 21 for exposing the plug 22. The trench hole is an area for a bottom-electrode of the capacitor.

All kind of silicon oxide including USG, PSG, TEOS, HTO, PE-TEOS and SOG can be used for material of the first and second insulating layers 21 and 23 and the first and second insulating layers can be formed by using methods of chemical vapor deposition (CVD) or a method of plasma enhanced CVD.

After forming the trench hole, the bottom-electrode is deposited on the second insulating layer 23. The deposited bottom-electrode is polished by performing a chemical mechanical polishing (CMP) until the second insulating layer 23 is exposed. Finally, the bottom-electrode 24 is formed only in the trench hole.

The bottom-electrode 24 is formed by using materials such as a poly-silicon, platinum (Pt), titanium nitride (TiN), a ruthenium (Ru), a ruthenium oxide (RuO₂), an iridium (IrO₂) and stacking any materials thereof.

After forming the bottom-electrode 24, the dielectric layer 25 is formed on the second insulating layer 23, which includes the bottom-electrode, and a forming process of the dielectric layer is performed at a comparatively low temperature of about 200° C. to about 700° C. and a thermal treatment process after forming the dielectric layer is performed in two steps.

If a deposition process of the dielectric layer is performed in a low temperature, the amorphous dielectric layer having low dielectric constant is formed as mentioned above. However, a deterioration of characteristics of element can be prevented by performing the thermal treatment process for crystallization of the dielectric layer and it also can prevent to produce an oxide having low permittivity between the dielectric layer and the bottom-electrode due to decreasing reaction with oxygen during deposition of dielectric layer in low temperature.

High dielectric substances, typical dielectric and feroelectric substances can be used for the dielectric layer, wherein the high elelectric substances are Ta₂O₅ and TaON, the typical dielectrics are SiO₂ or Si₃N₄ and the feroelectric substances include (Bi, La)₄Ti₃O₁₂ (BLT), SrBi₂Ta₂O₉ (SBT), SrxBiy(TaiNbj)₂O₉ (SBTN), BaxSr₍₁₋ₓ₎TiO₃ (BST) and Pb(Zr,Ti)O₃ (PZT). The dielectric layer is formed as about 50 Å to about 500 Å thickness by performing a method of chemical vapor deposition (CVD) or a method of atomic layer deposition (ALD) at a temperature of about 200° C. to about 700° C.

In the preferred embodiment of the present invention, a tantalum dielectric is used as the dielectric layer 25 and two steps of the thermal treatment processes are performed after forming the dielectric layer. A first step of the thermal treatment process is a process of crystallization of the tantalum dielectric layer 25 and a second step of the thermal treatment process is to supply oxygen to the tantalum dielectric layer 25 by performing a rapid thermal process at an ambient of abundant oxygen for a short period time in low or medium temperature.

The first thermal treatment process is a rapid thermal process (RTP) and performed for about 1 min. to about 3 min. at an ambient of nitrogen gas at a temperature of about 700° C. to about 900° C. for the crystallization of the tantalum dielectric layer 25.

The second thermal treatment process can use various methods. In detail, it can be performed at an ambient of various gas such as UV ozone (O₃), oxygen, oxygen plasma, N₂O, N₂O plasma, N₂+O₂, N₂+O₂ plasma and a mixture gas thereof for about 1 min. to about 3 min. (rapid thermal process) for supplying oxygen to the tantalum dielectric layer 25.

In the preferred embodiment of the present invention, the thermal treatment process of low temperature is performed to supply oxygen to the tantalum dielectric because the thickness of the tantalum dielectric is very thin so oxygen can be supplied to the tantalum dielectric in low temperature.

Also, the oxygen penetrates the tantalum dielectric layer 25 and the penetrated oxygen produces the oxide of low permittivity at the interface between the bottom-electrode and the dielectric layer. It is widely known that a depth of penetration of oxygen depends on the temperature. The low temperature thermal treatment process (400° C. to 700° C.) can decrease the depth of penetration, therefore it can prevent to produce the oxide at the interface between the bottom-electrode and the dielectric layer.

The above-mentioned two steps thermal treatment processes can prevent not only to produce the oxide of low permittivity at the interface between the bottom-electrode and the dielectric layer but also to supply sufficient oxygen to the dielectric therefore, the characteristics of the capacitor are improved.

After forming the tantalum dielectric layer 25, as shown in FIG. 2B, an upper-electrode 26 is formed on the dielectric layer 25. The upper-electrode 26 is formed by forming 300 Å thickness of a titanium nitride (TiN) and stacking with 1000 Å to 3000 Å thickness of doping poly-silicon 27.

After forming the upper-electrode 26, the thermal treatment process is performed at an ambient of nitrogen gas at a temperature of about 600° C. to about 800° C. for about 30 min or the rapid thermal process is performed with the nitrogen atmosphere for about 1 min. to about 3 min.

As mentioned above, the stacking layers of the titanium nitride and poly-silicon or a ruthenium, a ruthenium oxide, iridium or an iridium oxide can be used for the upper-electrode 26.

The present invention, as shown in FIG. 3, restrain to generate the oxide having low permittivity at the interface between the bottom-electrode 24 and the dielectric layer 25 by performing two steps of thermal treatment processes after depositing the dielectric layer 24 in low temperature. That is, the first thermal treatment process is performed in a short period time at an ambient of nitrogen gas for crystallizing the dielectric layer after depositing the dielectric layer at a low temperature and the second thermal treatment process is performed in a short period time at an ambient of oxygen in low or medium temperature for supplying oxygen to the dielectric. Therefore, the above-mentioned processes of the present invention can restrain the oxide having low permittivity.

The above-mentioned method for forming capacitor as a semiconductor element can increase a reliability and improve electrical characteristics.

While the present invention has been described with respect to certain preferred embodiments, it will be apparent to those skilled in the art that various changes and modifications may be made without departing from the scope of the invention as defined in the following claims.

What is claimed is:

1. A method for forming capacitor of a semiconductor device, comprising:
forming a bottom-electrode on a substrate;
forming a dielectric layer on the bottom-electrode;
performing a first thermal treatment process for crystallizing the dielectric layer;
performing a second thermal treatment process for supplying oxygen to the dielectric; and
forming an upper-electrode on the dielectric.

2. The method as recited in claim 1, wherein said first thermal treatment process is a rapid thermal process and performed at an ambient of a nitrogen gas at a temperature of about 700° C. to about 900° C. for approximate 1 min. to approximate 3 min.

3. The method as recited in claim 1, wherein said second thermal treatment process is a rapid thermal process and performed at an ambient of a oxygen gas, oxygen plasma gas, ozone (O₃) gas, N₂O gas, N₂O plasma gas, N₂+O₂ gas, N₂+O₂ plasma gas or a mixture gas thereof at a temperature of about 400° C. to about 700° C. for approximate 1 min. to approximate 3 min.

4. The method as recited in claim 1, wherein said step of forming said dielectric layer is performed at a substrate temperature of about 200° C. to about 700° C.

5. The method as recited in claim 1, wherein said dielectric is formed with material selected from a group consisting of Ta₂O₅, TaON, SiO₂/Si₃N₄, BLT, SBT, SBTN, BST and PZT.

6. The method as recited in claim 1, wherein said Ta₂O₅ and TaON is formed as about 50 Å to about 500 Å thickness by a method of chemical vapor deposition or a method of atomic layer deposition at a temperature of approximate 200° C. to approximate 700° C.

7. The method as recited in claim 1, wherein said bottom-electrode is formed with at least one selected from a group consisting of poly-silicon, platinum, ruthenium, ruthenium oxide, iridium, iridium oxide and titanium nitride.

8. The method as recited in claim 1, wherein said upper-electrode is formed by stacking titanium nitride and poly-silicon.

9. The method as recited in claim 1, wherein said step forming said upper-electrode further comprises the step of performing a thermal treatment process for the upper-electrode.

10. The method as recited in claim 9, wherein said step of performing the thermal treatment process is performed at an ambient of a nitrogen gas.

11. The method as recited in claim 10, wherein said thermal treatment process is performed at temperature of about 600° C. to about 800° C. for approximate 20 min to approximate 40 min at a furnace.

12. The method as recited in claim 10, wherein said thermal treatment process is a rapid thermal process and performed at a temperatures of approximate 600° C. to approximate 800° C. for about 1 min to about 3 min.
